(19) United States
(12) Patent Application Publication
(10) Pub. No.: US 2018/0218899 A1
(43) Pub. Date: Aug. 2, 2018

(54) ORIGINAL HOLDING APPARATUS, PATTERN FORMING APPARATUS, AND METHOD OF MANUFACTURING ARTICLE

(71) Applicant: CANON KABUSHIKI KAISHA, Tokyo (JP)

(72) Inventor: Yozo MATSUDA, Utsunomiya-shi (JP)

(21) Appl. No.: 15/746,643

(22) PCT Filed: Jul. 12, 2016
(86) PCT No.: PCT/JP2016/003288

§ 371 Date: Jan. 22, 2018

(30) Foreign Application Priority Data
Jul. 31, 2015 (JP) 2015-152689

(51) Int. Cl. H01L 21/027; G03F 7/00; B29C 43/02

(52) U.S. Cl. CPC H01L 21/0271; H01L 21/6838; B29C 43/02; G03F 7/0002

(57) ABSTRACT

An original holding apparatus of a simple arrangement and an arrangement in which a part does not protrude below an original in a normal operation state is provided. The original holding apparatus includes an original holding unit which holds the original, and a fall prevention mechanism which changes from the first state in which fall prevention of the original from the original holding unit is not performed to the second state in which fall prevention of the original is performed in response to the stop or lack of supply of a holding force holding the original to the original holding unit.

### TECHNICAL FIELD

The present invention relates to a fall prevention technique of an original in a pattern forming apparatus.

### BACKGROUND ART

In a lithography apparatus such as an imprint apparatus or an EUV exposure apparatus, an original (a mold or a reticle) is often held while facing downward. A chuck mechanism generally holds the original by vacuum chuck or electrostatic chuck. However, a mechanism which prevents falling of the original is needed in terms of fail-safe operation.

Japanese Patent Laid-Open No. 2006-156905 discloses a fall prevention mechanism that includes a support member which locks the lower surface of an original. Japanese Patent Laid-Open No. 2009-282111 discloses an arrangement in which a step is formed on the lower surface of a peripheral portion of an original to make the peripheral portion thinner, and a support member supports the lower surface of the thin peripheral portion.

In the arrangement of Japanese Patent Laid-Open No. 2006-156905, the support member of the fall prevention mechanism protrudes below the lower surface of the original even in a normal state. In an imprint apparatus as a mode of a lithography apparatus, the original and an imprint material on a substrate are brought into contact with each other. Therefore, if such a protruding portion exists in the lower portion of the original in a normal operation state, that protruding portion interferes with the substrate. Accordingly, the arrangement as in Japanese Patent Laid-Open No. 2006-156905 cannot be adopted to the imprint apparatus. In an arrangement in which a spacing between an original and a substrate is extremely small, it is also difficult to adopt the arrangement as in Japanese Patent Laid-Open No. 2006-156905 even to an exposure apparatus. As described above, the arrangement in Japanese Patent Laid-Open No. 2006-156905 has low versatility to the various lithography apparatuses including the imprint apparatus.

Further, in the arrangement in Japanese Patent Laid-Open No. 2009-282111, the shape of the original needs to be changed. Changing the shape of the original has influences on many steps such as a manufacturing step of the original and a step of drawing a pattern on the original, causing an increase in cost and a delay in a process.

### SUMMARY OF INVENTION

The present invention provides an original holding apparatus of, for example, a simple arrangement and an arrangement in which a part does not protrude below an original in a normal operation state.

According to one aspect of the present invention, an original holding apparatus is provided. The apparatus comprises an original holding unit configured to hold an original, and a fall prevention mechanism configured to change from a first state in which fall prevention of the original from the original holding unit is not performed to a second state in which fall prevention of the original is performed in response to one of a stop and a lack of supply of a holding force holding the original to the original holding unit.

Further features of the present invention will become apparent from the following description of exemplary embodiments (with reference to the attached drawings).

### BRIEF DESCRIPTION OF DRAWINGS

FIG. 1 is a view showing the arrangement of an imprint apparatus according to an embodiment;

FIG. 2A is a view showing an arrangement example of a fall prevention mechanism;

FIG. 2B is a view showing an arrangement example of a fall prevention mechanism;

FIG. 3A is a view showing another arrangement example of the fall prevention mechanism;

FIG. 3B is a view showing another arrangement example of the fall prevention mechanism;

FIG. 4A is a view showing still another arrangement example of the fall prevention mechanism;

FIG. 4B is a view showing still another arrangement example of the fall prevention mechanism;

FIG. 5A is a view showing still another arrangement example of the fall prevention mechanism;

FIG. 5B is a view showing still another arrangement example of the fall prevention mechanism;

FIG. 6A is a view showing still another arrangement example of the fall prevention mechanism;

FIG. 6B is a view showing still another arrangement example of the fall prevention mechanism;

FIG. 7A is a view showing an example of the arrangement in which a lock member is returned to a retracted position;

FIG. 7B is a view showing an example of the arrangement in which a lock member is returned to a retracted position;

FIG. 8A is a view showing an example of the arrangement in which the lock member is returned to the retracted position;

FIG. 8B is a view showing an example of the arrangement in which the lock member is returned to the retracted position;

FIG. 9A is a view showing an example in which the fall prevention mechanisms are arranged at the four corners of a mold;

FIG. 9B is a view showing an example in which the fall prevention mechanisms are arranged at the four corners of a mold;

FIG. 10A is a view showing an example of the arrangement in which a vacuum path is coupled outside the fall prevention mechanism; and

FIG. 10B is a view showing an example of the arrangement in which a vacuum path is coupled outside the fall prevention mechanism.

### DESCRIPTION OF EMBODIMENTS

Various exemplary embodiments, features, and aspects of the invention will be described in detail below with reference to the drawings. Note that the following embodiments are not intended to limit the present invention and are merely concrete examples advantageous in practicing the invention. Also, not all combinations of features to be described in the embodiments are indispensable for the means to solve the problems according to the present invention.

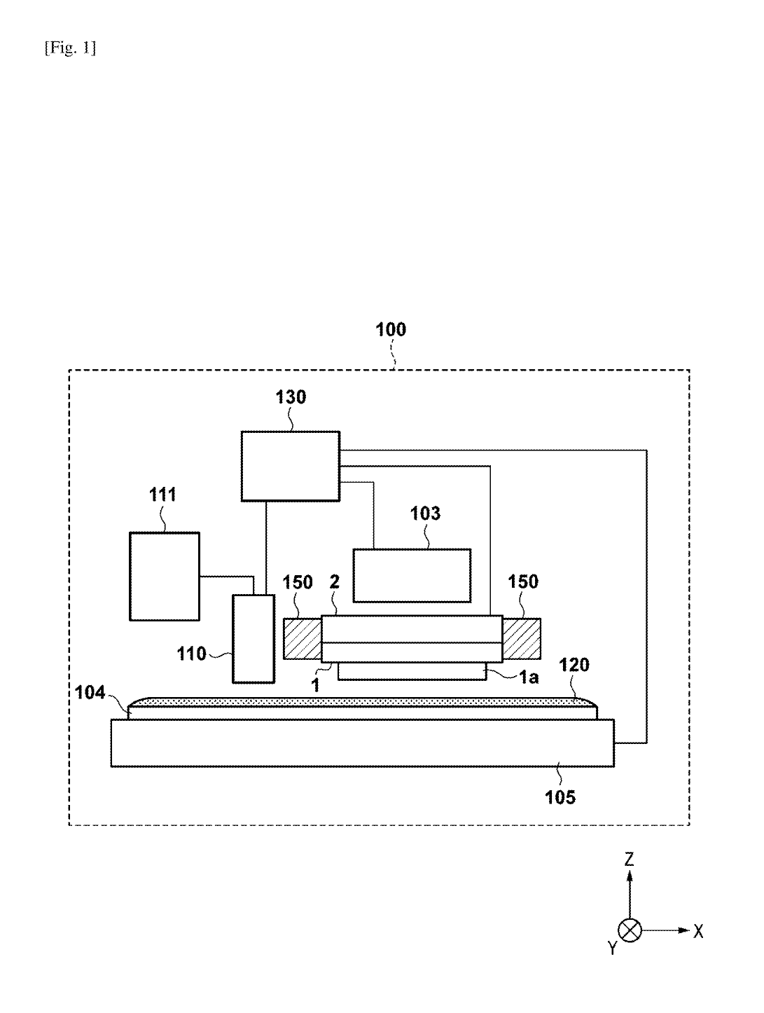

FIG. 1 is a view showing the arrangement of an imprint apparatus 100 according to this embodiment to which an original holding apparatus of an original of the present invention is applied. The imprint apparatus 100 is a lithography apparatus (pattern forming apparatus) used in a manufacturing process of a semiconductor device or the like. The imprint apparatus 100 forms a pattern in an imprint material (for example, a resin) on a substrate by using a mold as an original. In this embodiment, the imprint apparatus 100 adopts, as a method of curing the imprint material, a photo-curing method of curing the imprint material (photocuring resin) by ultraviolet light irradiation. However, the present invention is not limited to this. For example, a heat-curing method using a thermosetting resin may be adopted.

A mold 1 includes, on a surface facing a substrate 104, a pattern portion 1a where a pattern that should be transferred to an imprint material 120 supplied onto the substrate 104 is formed. The mold 1 has, for example, a rectangular outer shape and is made of a material such as quartz that transmits ultraviolet light.

A mold holding unit 2 (original holding unit) chucks and holds the upper surface of the mold 1 by a vacuum suction force or an electrostatic force. The mold holding unit 2 includes a driving mechanism which drives the mold 1 in the z-axis direction (the direction perpendicular to the surface of the substrate 104). With this driving mechanism, the mold holding unit 2 brings the mold 1 and the imprint material 120 (uncured resin) applied on the substrate 104 into contact with each other by narrowing the spacing between the mold 1 and the substrate 104 (mold pressing). An ultraviolet light emitting unit 103 emits ultraviolet light in a state in which the imprint material 120 and the mold 1 are in contact with each other, curing the imprint material 120. Then, the mold holding unit 2 separates the mold 1 from the cured imprint material on the substrate 104 by enlarging the spacing between the mold 1 and the substrate 104 (releasing). A case in which mold pressing and releasing are performed by driving the mold holding unit 2 has been described here. However, the spacing between the mold 1 and the substrate 104 may be narrowed or enlarged by driving a substrate stage 105 which holds the substrate 104. Mold pressing and releasing may also be performed by relatively driving the mold holding unit 2 and the substrate stage 105.

The substrate 104 includes, for example, a single-crystal silicon wafer or an SOI (Silicon on Insulator) wafer. The substrate stage 105 includes a substrate chuck which holds the substrate 104, and a driving mechanism configured to perform alignment between the mold 1 and the substrate 104. For example, this driving mechanism may be formed by a coarse driving system and a fine driving system, and have a function of driving the substrate 104 in the x-axis direction, the y-axis direction, and the 0 direction (rotational direction around the z-axis) and a tilt function of correcting the tilt of the substrate 104.

An imprint material supply unit 111 is a tank which stores an uncured imprint material and supplies it to a dispenser 110 by a pipe. The dispenser 110 serving as a coating unit of the imprint material includes orifices for applying the imprint material 120 onto the substrate 104 by, for example, an inkjet method. The imprint material 120 supplied from the imprint material supply unit 111 is applied onto the substrate 104 by moving the substrate stage 105 while the dispenser 110 discharges the imprint material 120.

A controller 130 includes, for example, a CPU and a memory, and controls the overall operation of the imprint apparatus 100. The controller 130 controls the respective units of the imprint apparatus 100 and functions as a processing unit which performs an imprint process. Note that the imprint process of forming the pattern of the imprint material on the substrate includes the following operation. In this embodiment, the imprint material 120 is applied for each shot region of the substrate 104. Then, the controller 130 brings the mold 1 into contact with the imprint material 120 in each shot region of the substrate 104 (molding pressing) and causes the ultraviolet light emitting unit 103 to emit the ultraviolet light for a predetermined time in that state, curing the imprint material. Then, the controller 130 separates the mold 1 from the cured imprint material (releasing). Consequently, the pattern of the imprint material 120 is formed on the substrate 104.

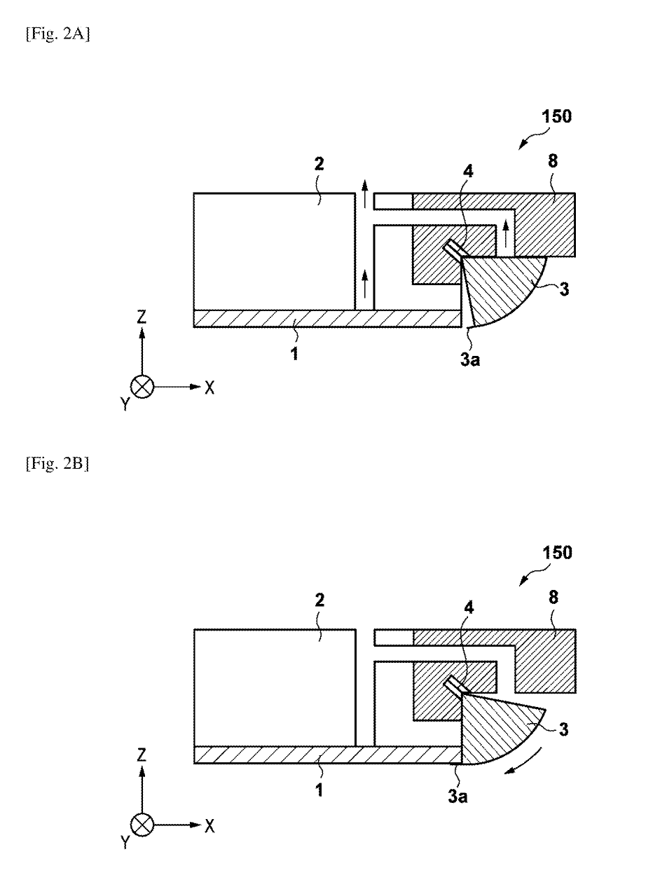

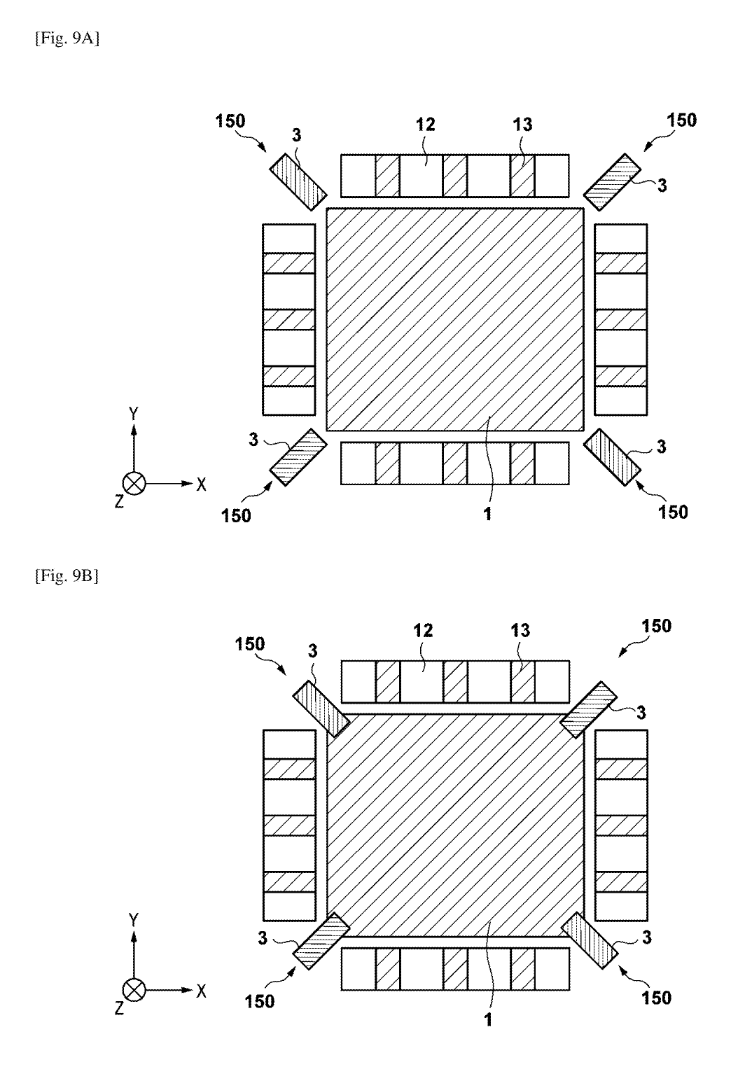

In this embodiment, the original holding apparatus in the imprint apparatus 100 includes the mold holding unit 2 (original holding unit) and fall prevention mechanisms 150 which prevent falling of the mold 1 from the mold holding unit 2. The fall prevention mechanisms 150 can change from the first state in which fall prevention of the mold from the mold holding unit 2 is not performed to the second state in which fall prevention of the mold is performed in response to the stop or lack of supply of an original holding force for holding the mold 1 to the mold holding unit 2. Each of FIGS. 2A and 2B shows an arrangement example of the fall prevention mechanism 150. The plurality of fall prevention mechanisms 150 can be provided around the mold 1 (details of which will be described later with reference to each example of FIGS. 9A and 9B). However, in each example of FIGS. 2A and 2B to FIGS. 8A and 8B to be described below, only one out of the plurality of fall prevention mechanisms 150 is shown.

In FIG. 2A, the mold holding unit 2 chucks and holds the upper surface of the mold 1 by a vacuum pressure. The fall prevention mechanism 150 includes a lock member 3 for locking the mold 1. The fall prevention mechanism 150 also includes a displacement mechanism which displaces the lock member 3. In this embodiment, such a displacement mechanism can include a hinge member 4 which supports the lock member 3 to be rotationally movable. The fall prevention mechanism 150 further includes a lock member holding unit 8 which chucks and holds the lock member 3. A support member 3a for supporting the mold 1 from below is provided in the lower end portion of the lock member 3. For example, the lock member holding unit 8 shares a vacuum pressure mechanism with the mold holding unit 2 and chucks, in an operation state (normal operation state) of the imprint apparatus 100, the lock member 3 with a vacuum pressure by the vacuum pressure mechanism. Note that the lock member holding unit 8 may be formed as a part of the mold holding unit 2 or may be arranged separately from the mold holding unit 2. Let a “retracted position” (first position) be a position at which the lock member holding unit 8 chucks the lock member 3. This retracted position is a position at which fall prevention of the mold is not performed, and spaced apart from the mold 1 on the side of the mold 1 and above the lower surface of the mold 1. This makes it possible to arrange a part also in the lower portion of the mold 1. Note that the lower portion of the mold 1 indicates, for example, a range surrounded by the distance of 10 mm from the lower surface of the mold 1 in the vertical direction and the radius of the substrate 104 from the center of the mold 1 in the horizontal direction.

The lock member 3 needs to support (hold) the mold 1 before the mold 1 falls from the mold holding unit 2. To do this, in a process of decreasing a chucking force because of the stop or lack of supply of the vacuum pressure serving as the original holding force of the mold by the mold holding unit 2, design needs to be made such that the lock member 3 first moves to support the mold 1, and then the mold 1 drops off the mold holding unit 2.

Note that the following relations hold among the chucking pressure, the chucking area, and the mass of the mold 1 with respect to the mold holding unit 2, the chucking pressure and the chucking area of the lock member 3 with respect to the lock member holding unit 8, and the mass and gravitational acceleration g of the lock member 3.

P1*S1=M1*g

P2*S2=M2*g

where P1: a chucking pressure of the mold 1

S1: a chucking area of the mold 1

M1: a mass of the mold 1

P2: a chucking pressure of the lock member 3

S2: a chucking area of the lock member 3

M2: a mass of the lock member 3

g: gravitational acceleration

In a case in which the mold 1 and the lock member 3 are equal in chucking pressure, and the chucking pressure decreases by the same value also when the vacuum pressure decreases (that is, a case in which P1=P2 always holds), design can be made such that the following relation holds between the mold 1 and the lock member 3.

M1/S1<M2/S2

That is, the lock member 3 can be made larger than the mold 1 in mass per chucking area. If this relation is satisfied, in the process of decreasing the chucking pressure because of the stop or lack of supply of the vacuum pressure serving as the holding force, the lock member 3 first moves downward by a self weight to lock (hold) the mold 1, and then the mold 1 is removed from the mold holding unit 2. FIG. 2B shows a state in which the lock member 3 moves downward to lock the mold 1. Let a “fall prevention position” (second position) be a position of the lock member 3 when fall prevention of this mold 1 is performed.

On the other hand, a case is considered in which the chucking pressure decreases by values different between the mold 1 and the lock member 3 (that is, in the case of P1≠P2). In this case, letting Pf1 be a pressure when the mold 1 falls and Pf2 be a pressure when the lock member 3 moves downward, design can be made such that P2 reaches Pf2 earlier than time at which P1 reaches Pf1. For example, a speed at which a pressure decreases can be reduced by providing a large-volume tank in a vacuum path or providing a restrictor.

Even in the state of FIG. 2B, if a gap between the lock member 3 and a chucking portion in the upper portion of the lock member 3 is set sufficiently small, the lock member 3 is chucked upward again when the holding force is applied again. In this case, the mold holding unit 2 chucks and holds the mold 1, and then the lock member holding unit 8 chucks the lock member 3. In an example of FIG. 2, the lock member 3 has a degree of freedom in the rotational direction by using the hinge member 4 as a fulcrum. In a normal state, the lock member 3 stays at the retracted position by the vacuum pressure serving as the holding force, and moves to the fall prevention position downward by a gravity serving as a restoring force if the vacuum pressure decreases for some reason. The restoring force refers to a force with which an object tries to be restored to an original position or shape. If gravity is utilized, the restoring force refers to a force with which the object tries to be restored to the original position when it is raised to a certain height by another force. If an elastic force is utilized, the restoring force refers to a force with which the object tries to be restored to the original shape when it is deformed into a certain shape by another force. Further, if a magnetic force is utilized, the restoring force refers to a force with which the object tries to be restored to the original position when it is brought closer to an opposing magnet of the same pole by another force.

In each of FIGS. 2A and 2B, the hinge member 4 may be an elastic hinge biased in the direction of the fall prevention position. The hinge member 4 can apply a force to the lock member 3 in a direction from the retracted position to the fall prevention position. The holding force of the mold 1 by the lock member 3 can be increased by using the elastic hinge biased in the direction of the fall prevention position.

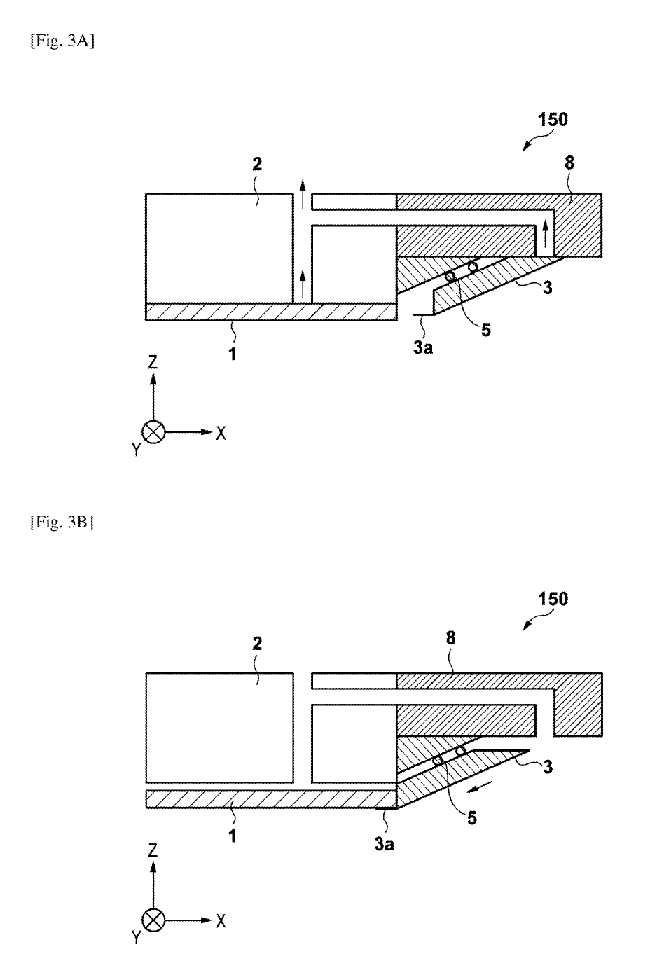

Each of FIGS. 3A and 3B shows another arrangement example of the fall prevention mechanism 150. In the example of FIGS. 3A and 3B, the fall prevention mechanism 150 includes a linear guide 5 which supports the lock member 3 slidably. With this linear guide 5, the lock member 3 has the degree of freedom in one axial direction which connects the retracted position and the fall prevention position. In the normal state, the lock member 3 stays at the retracted position by the vacuum pressure serving as a holding motive force (FIG. 3A), and moves toward the fall prevention position by the gravity serving as the restoring force (FIG. 3B) if the vacuum pressure decreases for some reason.

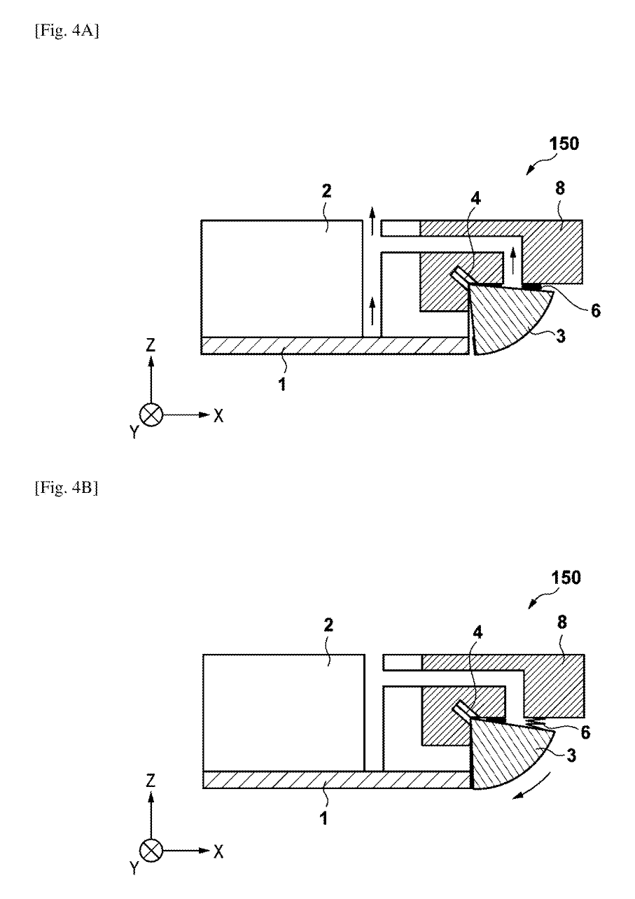

Each of FIGS. 4A and 4B shows still another arrangement example of the fall prevention mechanism 150. The arrangement of FIGS. 4A and 4B is the same as that of FIGS. 2A and 2B. In the example of FIGS. 4A and 4B, however, a bias member 6 biased in the direction from the retracted position to the fall prevention position is provided between the lock member 3 and the lock member holding unit 8. The bias member 6 can apply a force to the lock member 3 in the direction from the retracted position to the fall prevention position. The bias member 6 can be, for example, an elastic member such as a spring. In the normal state, the vacuum pressure serving as the holding motive force exceeds the elastic force of the bias member 6, and the lock member 3 stays at the retracted position (FIG. 4A). Then, in response to the stop or lack of supply of the original holding force to the mold holding unit 2, the lock member 3 moves toward the fall prevention position by a biasing force and the gravity of the bias member 6 (FIG. 4B).

According to this arrangement, it is possible to make sure that the lock member 3 holds the mold 1 before the mold 1 falls from the mold holding unit 2. It is also possible to increase, by the biasing force of the bias member 6, the holding force of the mold 1 by the lock member 3. When the holding force of the mold 1 is obtained sufficiently by this bias member 6, the lock member 3 can be held only on the side surface of the mold 1 by removing the support member 3a shown in each of FIGS. 2A and 2B. Therefore, there is an advantage that the lock member 3 can hold the mold 1 even if there is no gap between the mold 1 and the substrate 104. Employing a tabular elastic member for the bias member 6 and using the interior thereof as a vacuum path, re-chucking is easy when the holding motive force is applied again even if the gap between the lock member 3 and the chucking portion in the upper portion of the lock member 3 is large.

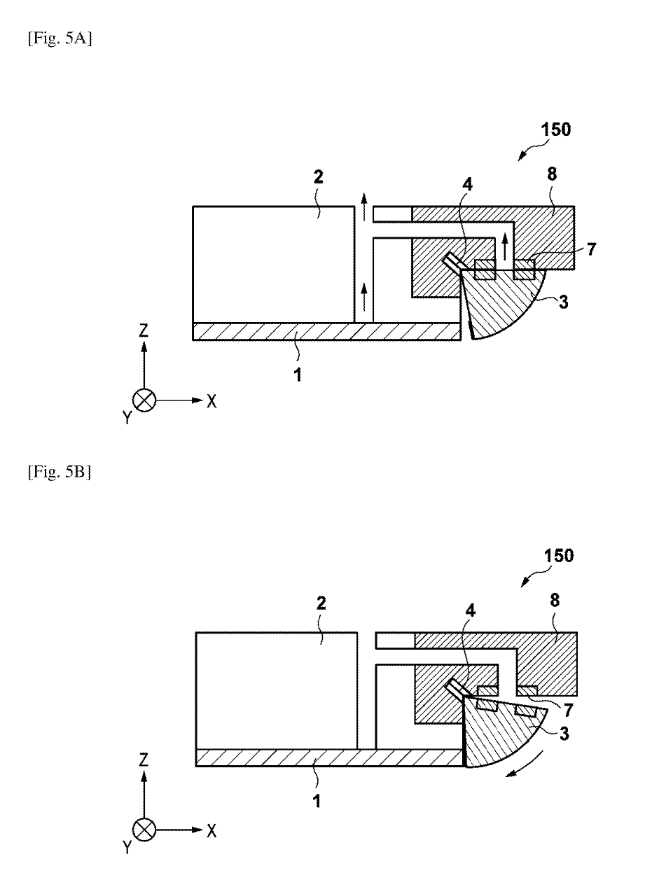

Each of FIGS. 5A and 5B shows still another arrangement example of the fall prevention mechanism 150. In the example of FIGS. 4A and 4B, the elastic member such as the spring is used for the bias member 6. In the example of FIGS. 5A and 5B, however, magnets 7 are used as another mode of the bias member 6. In each of FIGS. 5A and 5B, at least a pair of the magnets 7 whose same poles face each other at the retracted position is provided on respective surfaces where the lock member 3 and the lock member holding unit 8 face each other. In the normal state, the vacuum pressure serving as the holding motive force exceeds a repulsive magnetic force of each magnet 7, and the lock member 3 stays at the retracted position (FIG. 5A). Then, if the vacuum pressure decreases for some reason, the lock member 3 moves toward the fall prevention position by a repulsive force and the gravity of each magnet 7 each serving as the restoring force (FIG. 5B). According to this arrangement, it is possible to obtain the same effect as in each arrangement of FIGS. 4A and 4B.

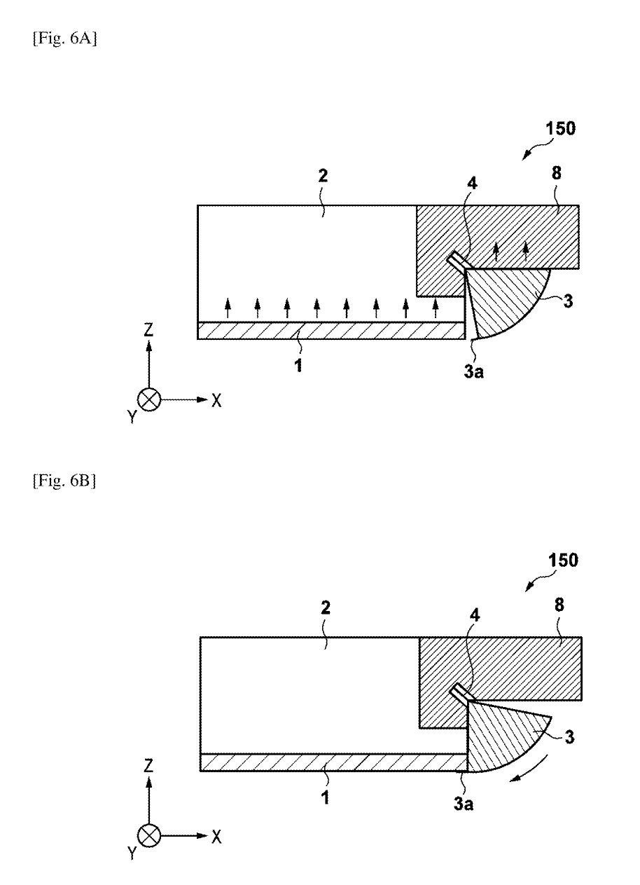

Each of FIGS. 6A and 6B shows still another arrangement example of the fall prevention mechanism 150. In the example of FIGS. 2A and 2B, the holding motive force of each of the mold holding unit 2 and the lock member holding unit 8 is the vacuum suction force. In the example of FIGS. 6A and 6B, however, the holding motive force of each of the mold holding unit 2 and the lock member holding unit 8 is the electrostatic force. FIG. 6A shows a state in which the mold 1 and the lock member 3 are chucked to the mold holding unit 2 and the lock member holding unit 8, respectively, by the electrostatic force. FIG. 6B shows a state in which the electrostatic force decreases, and the lock member 3 moves to the fall prevention position to hold the mold 1. Note that when the holding motive force is the electrostatic force, the lock member 3 needs to be electrically insulated from the lock member holding unit 8.

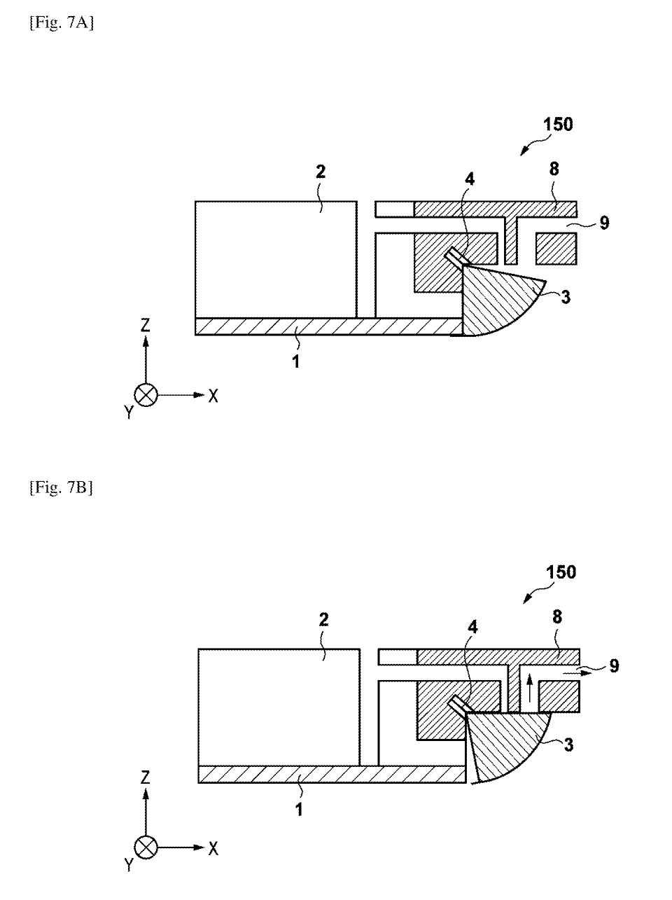

After being activated, the fall prevention mechanism 150 can include a return unit which returns the lock member 3 from the fall prevention position to the retracted position. FIG. 7A shows a state in which the fall prevention mechanism 150 is activated, that is, a state in which the lock member 3 moves to the fall prevention position. As shown in each of FIGS. 7A and 7B, the return unit can include a vacuum path 9 for returning the lock member 3 to the retracted position. An external vacuum apparatus (not shown) is connected to this vacuum path 9. By operating the external vacuum apparatus in the state of FIG. 7A, air is sucked via the vacuum path 9, and the lock member 3 is removed from the mold 1 and chucked to the lock member holding unit 8. This makes it possible to return the lock member 3 to the retracted position. This also makes it possible to recover the mold 1 without being disturbed by the fall prevention mechanism 150.

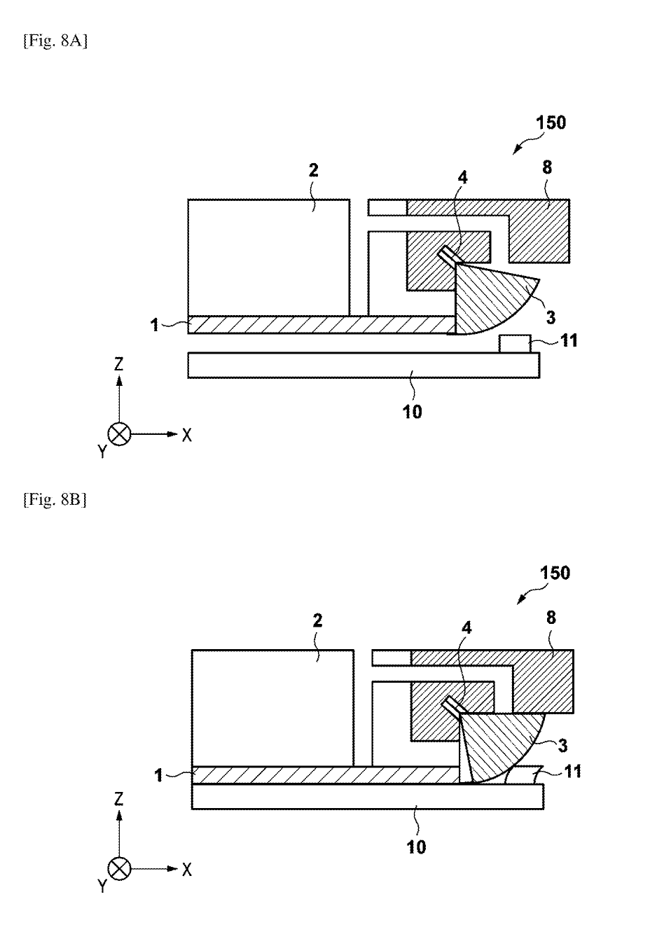

Each of FIGS. 8A and 8B shows another example of the return unit. An original conveyance unit 10 performs mounting and recovery of the mold 1 on the mold holding unit 2. A guide member 11 serving as the return unit is provided on this original conveyance unit 10. FIG. 8A shows a state in which the fall prevention mechanism 150 is activated, that is, a state in which the lock member 3 moves to the fall prevention position. In this state, the original conveyance unit 10 is moved upward from below the mold 1. Along with this movement, the guide member 11 abuts against the lock member 3, making it possible to push up the lock member 3 from below and return it to the retracted position (FIG. 8B).

The relationship between the fall prevention mechanisms and surrounding units will now be described. Each of FIGS. 9A and 9B is a view showing the mold 1 when viewed from the bottom. Note that the fall prevention mechanisms 150 include the plurality of lock members 3 described above. In the example of FIGS. 9A and 9B, four lock members 3 are arranged at the four corners of the mold 1 having a rectangular shape. In general, other units are close to the four side portions of the mold 1. For example, original shape correction mechanisms 12 and fluid supply/recovery units 13 can be arranged in the four side portions of the mold 1. Each fall prevention mechanism 150 of the above-described embodiment has the simple driving mechanism of the lock member 3. This allows the fall prevention mechanisms 150 to have compact design and be arranged at the four corners so as not to interfere with the other units described above.

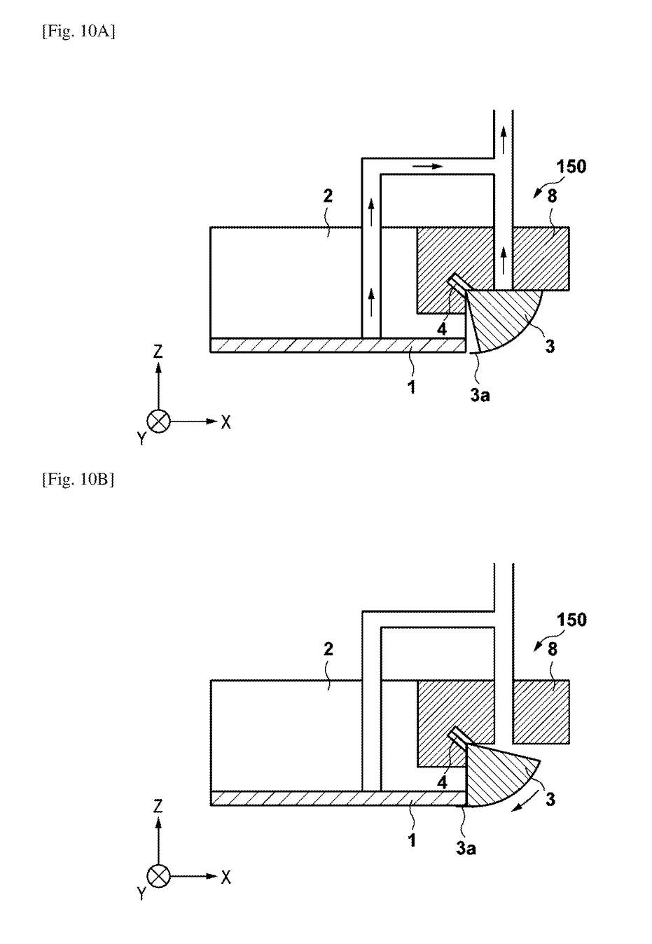

In the example of FIGS. 2A and 2B, an arrangement is shown in which the vacuum path of the mold holding unit 2 and the vacuum path of the lock member holding unit 8 are coupled to each other inside the fall prevention mechanism 150. However, the present invention is not limited to this. As shown in each of FIGS. 10A and 10B, an arrangement may also be possible in which the vacuum path of the mold holding unit 2 and the vacuum path of the lock member holding unit 8 are coupled to each other outside the fall prevention mechanism 150. Also in the arrangement of FIGS. 10A and 10B, as in FIGS. 2A and 2B, the lock member 3 stays at the retracted position by the vacuum pressure serving as the holding motive force in the normal state (FIG. 10A). Then, if the vacuum pressure decreases for some reason, the lock member 3 moves to the fall prevention position by the self weight of the lock member 3 (FIG. 10B).

An example has been described in which the above-described embodiment is applied to the imprint apparatus. However, the above-described embodiment is also applicable to the lithography apparatus other than the imprint apparatus. For example, the upper surface of an original is held also in the EUV exposure apparatus, and thus the fall prevention mechanism as in the above-described embodiment is applicable. In order to evacuate a space in the EUV exposure apparatus, a partition wall is provided in each place. A partition wall is often provided also between the original and a lens barrel to be scan-driven. Since there is a small space below the original, the above-described embodiment is useful.

Embodiment of Method of Manufacturing Article

A method of manufacturing an article according to an embodiment of the present invention is suitable for manufacturing an article, for example, a microdevice such as a semiconductor device or an element having a microstructure. The method of manufacturing the article according to this embodiment includes a step of transferring the pattern of an original onto a substrate using the above-described lithography apparatus (an exposure apparatus, an imprint apparatus, a drawing apparatus, or the like), and a step of processing the substrate onto which the pattern has been transferred in the preceding step. This manufacturing method further includes other known steps (oxidation, deposition, vapor deposition, doping, planarization, etching, resist removal, dicing, bonding, packaging, and the like). The method of manufacturing the article according to this embodiment is advantageous in at least one of the performance, the quality, the productivity, and the production cost of the article, as compared to a conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-152689, filed Jul. 31, 2015, which is hereby incorporated by reference herein in its entirety.

1. An original holding apparatus comprising:
an original holding unit configured to hold an original; and
a fall prevention mechanism configured to change from a first state in which fall prevention of the original from the original holding unit is not performed to a second state in which fall prevention of the original is performed in response to one of a stop and a lack of supply of a holding force holding the original to the original holding unit.

2. The apparatus according to claim 1, wherein the fall prevention mechanism includes
a lock member configured to lock the original, and
a displacement mechanism configured to position the lock member at a first position retracted from the original in the first state and displace the lock member to a second position at which fall prevention of the original is performed when changing the first state to the second state.

3. The apparatus according to claim 2, wherein the displacement mechanism includes a hinge member configured to support the lock member to be rotationally movable between the first position and the second position.

4. The apparatus according to claim 2, wherein the displacement mechanism includes a linear guide configured to support the lock member slidably between the first position and the second position.

5. The apparatus according to claim 3, wherein the lock member is displaced from the first position to the second position by a self weight.

6. The apparatus according to claim 2, wherein the first position is a position on a side of the original and above a surface of the original on which a pattern of the original has been formed.

7. The apparatus according to claim 2, wherein the fall prevention mechanism includes a lock member holding unit configured to hold the lock member at the first position by a holding force of the original holding unit in the first state.

8. The apparatus according to claim 3, wherein the hinge member comprises an elastic hinge biased in a direction from the first position to the second position.

9. The apparatus according to claim 2, wherein the lock member includes a support member configured to support the original from below at the second position.

10. The apparatus according to claim 7, wherein the fall prevention mechanism includes a bias member provided between the lock member and the lock member holding unit, and configured to bias the lock member in a direction from the first position to the second position.

11. The apparatus according to claim 7, wherein the fall prevention mechanism includes a return unit configured to return the lock member from the second position to the first position.

12. The apparatus according to claim 11, wherein the return unit includes a vacuum path formed in the lock member holding unit and connected to an external vacuum apparatus.

13. The apparatus according to claim 11, wherein the return unit includes a guide member which is provided in an original conveyance unit configured to perform, on the original, conveyance to the original holding unit and recovery from the original holding unit and abuts against the lock member to return the lock member from the second position to the first position as the original conveyance unit moves upward from below the original.

14. The apparatus according to claim 1, wherein the fall prevention mechanism includes a plurality of fall prevention mechanisms, and the fall prevention mechanisms are provided at four corners of the original having a rectangular shape.

15. A patter forming apparatus which forms a pattern formed in an original on a substrate, the apparatus comprising:
an original holding apparatus configured to hold the original,
wherein the original holding apparatus includes
an original holding unit configured to hold the original; and
a fall prevention mechanism configured to change from a first state in which fall prevention of the original from the original holding unit is not performed to a second state in which fall prevention of the original is performed in response to one of a stop and a lack of supply of a holding force holding the original to the original holding unit.

16. A method of manufacturing an article, the method comprising:
forming a pattern on a substrate using a pattern forming apparatus; and
processing the substrate on which the pattern has been formed in the forming, wherein the article is manufactured from the processed substrate;
wherein the patter forming apparatus includes an original holding apparatus which holds an original, and
the original holding apparatus includes
an original holding unit configured to hold the original, and
a fall prevention mechanism configured to change from a first state in which fall prevention of the original from the original holding unit is not performed to a second state in which fall prevention of the original is performed in response to one of a stop and a lack of supply of a holding force holding the original to the original holding unit.
